(19) United States
(12) Patent Application Publication
(10) Pub. No.: US 2008/0157118 A1
(43) Pub. Date: Jul. 3, 2008

(54) INTEGRATED CIRCUIT SYSTEM EMPLOYING STRAINED TECHNOLOGY

(75) Inventors: Jae Gon Lee, Singapore (SG); Lee Wee Teo, Singapore (SG); Seong-dong Kim, Lagrangeville, NY (US)

Correspondence Address: LAW OFFICES OF MIKIO ISHIMARU, 333 W. EL CAMINO REAL, SUITE 330, SUNNYVALE, CA, 94087, US

(73) Assignees: CHARTERED SEMICONDUCTOR MANUFACTURING LTD., Singapore (SG); INTERNATIONAL BUSINESS MACHINES CORPORATION, Armonk, NY (US)

(21) Appl. No.: 11/618,453

(22) Filed: Dec. 29, 2006

(51) Int. Cl. H01L 27/092; H01L 21/8238

(52) U.S. Cl. 257/190; 438/199; 257/E27.062; 257/E21.632

(57) ABSTRACT

An integrated circuit system that includes: providing a substrate with a PMOS device and an NMOS device; forming an NMOS shallow recess within the substrate; forming a PMOS recess within the substrate; forming a strain inducing layer over the PMOS recess; forming a first dielectric layer over the NMOS device and a second dielectric layer over the PMOS device.

### TECHNICAL FIELD

The present invention relates generally to integrated circuits, and more particularly to an integrated circuit system employing strained technology.

### BACKGROUND ART

A conventional metal-oxide-semiconductor field-effect transistor (MOSFET) generally includes a semiconductor substrate, having a source, a drain, and a channel located between the source and drain. A gate stack composed of a conductive material (i.e.—a gate) and an oxide layer (i.e.—a gate oxide) are typically located directly above the channel. During operation, an inversion layer forms a conducting bridge or “channel” between the source and drain when a voltage is applied to the gate. Both p-channel and n-channel MOSFET technologies are available and can be combined on a single substrate in one technology, called complementary-metal-oxide-semiconductor or CMOS. This conventional MOSFET design (both p-channel and n-channel) finds application in many of today's consumer electronics, such as cellphones, video cameras, portable music players, computers, etc.

Scaling of the MOSFET, whether by itself or in a CMOS configuration, has become a major challenge for the semiconductor industry. Size reduction of the integral parts of a MOSFET has lead to improvements in device operation speed and packing density, but size reduction has its limits. For example, as scaling of the MOSFET reaches the submicron era, short channel effects and punchthrough phenomena become a design problem as the reduction of the gate length and gate oxide thickness start to fail in their ability to reduce these detrimental physical effects. Consequently, new methods must be developed to maintain the expected device performance enhancement from one generation of devices to the next.

Generally, the amount of current that flows through the channel of a transistor is directly proportional to the mobility of carriers within the channel region. Consequently, the higher the mobility of the carriers in the transistor channel, the more current that can flow through the device and the faster it can operate. One way to increase the mobility of carriers in the channel of a transistor is to manufacture the transistor with a strained channel. Depending upon the type of strained channel, significant carrier mobility enhancement has been reported for both electrons and holes. Commonly, a compressively strained channel exhibits enhanced hole mobility and a tensile strained channel exhibits enhanced electron mobility.

A conventional approach for introducing strain into the transistor channel region is achieved by forming an epitaxial silicon layer over a relaxed SiGe layer. Due to the larger lattice constant between adjacent atoms of the SiGe layer, the epitaxially grown silicon layer will have its lattice stretched in a lateral direction that is parallel to the surface of the SiGe layer. This lattice mismatching between the epitaxially grown silicon layer and the SiGe layer causes a biaxial tensile strain within the channel region (i.e.—the silicon layer). It is well known within the art that tensile strained channel regions can achieve significant electron mobility enhancement. Unfortunately, the attainment of the relaxed SiGe layer can be costly to achieve and subsequent high temperature processing steps can eliminate any strain induced by the SiGe layer.

Thus, a need still remains for a reliable integrated circuit system and method of fabrication, wherein the integrated circuit system exhibits improved carrier mobility due to the application of stress to the channel. In view of the ever-increasing commercial competitive pressures, increasing consumer expectations, and diminishing opportunities for meaningful product differentiation in the marketplace, it is increasingly critical that answers be found to these problems. Moreover, the ever-increasing need to save costs, improve efficiencies, and meet such competitive pressures adds even greater urgency to the critical necessity that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including: providing a substrate with a PMOS device and an NMOS device; forming an NMOS shallow recess within the substrate; forming a PMOS recess within the substrate; forming a strain inducing layer over the PMOS recess; forming a first dielectric layer over the NMOS device and a second dielectric layer over the PMOS device.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is an integrated circuit system in an initial stage of manufacture in accordance with an embodiment of the present invention;

FIG. 2 is the structure of FIG. 1 after formation of an insulation layer;

FIG. 3 is the structure of FIG. 2 after selective etching;

FIG. 4 is the structure of FIG. 3 after the formation of a PMOS recess within the substrate;

FIG. 5 is the structure of FIG. 4 after further processing;

FIG. 6 is the structure of FIG. 5 after the selective formation of a strain inducing layer over the PMOS source/drain;

FIG. 7 is the structure of FIG. 6 after the removal of the insulation layer from over the NMOS device;

FIG. 8 is the structure of FIG. 7 after further processing;

FIG. 9 is the structure of FIG. 8 after deposition of a first dielectric layer and a second dielectric layer;

FIG. 10 is an integrated circuit system in an initial stage of manufacture in accordance with an embodiment of the present invention;

FIG. 11 is the structure of FIG. 10 after formation of an insulation layer;

FIG. 12 is the structure of FIG. 11 after etching an insulation layer;

FIG. 13 is the structure of FIG. 12 after the formation of a PMOS recess within the substrate;

FIG. 14 is the structure of FIG. 13 after the selective formation of a strain inducing layer over a PMOS source/drain;

FIG. 15 is the structure of FIG. 14 after the removal of an insulation layer from over an NMOS device;

FIG. 16 is the structure of FIG. 15 after further processing;

FIG. 17 is the structure of FIG. 16 after deposition of a first dielectric layer and a second dielectric layer;

FIG. 18 is the structure of FIG. 9 with a strain suppressing feature in accordance with the first embodiment of the present invention; and

FIG. 19 is a flow chart of an integrated circuit system for an integrated circuit system in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

Likewise, the drawings showing embodiments of the system are semi-diagrammatic and not to scale and, particularly, some of the dimensions are for the clarity of presentation and are shown exaggerated in the drawing FIGs. Additionally, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane. The term “processing” as used herein includes deposition of material or photoresist, patterning, exposure, development, etching, cleaning, and/or removal of the material or photoresist as required in forming a described structure.

### First Embodiment

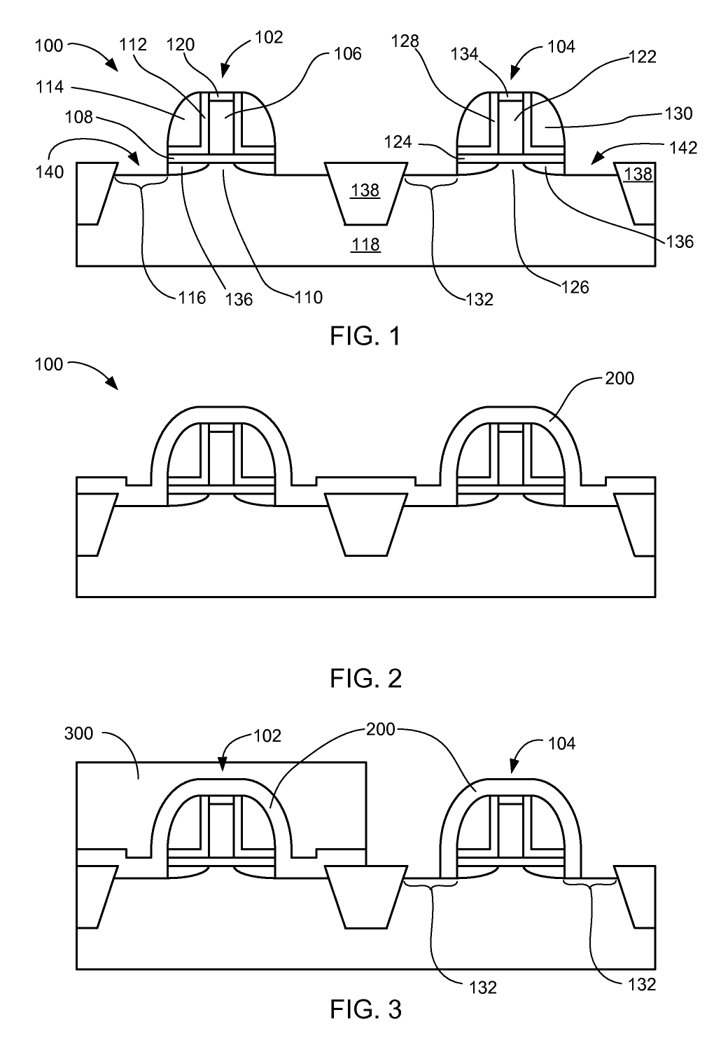

FIGS. 1-9 depict by way of example and not by limitation, an exemplary process flow for the formation of an integrated circuit system 100, and it is not to be construed as limiting.

Referring now to FIG. 1, therein is shown the integrated circuit system 100 in an initial stage of manufacture in accordance with an embodiment of the present invention. The integrated circuit system 100 can be formed from conventional deposition, patterning, photolithography, and etching to form an NMOS device 102 and a PMOS device 104. The NMOS device 102 and the PMOS device 104 may operate together, thereby forming a complementary metal-oxide-semiconductor (CMOS) configuration.

The NMOS device 102 includes an NMOS gate 106. Below the NMOS gate 106 is an NMOS gate oxide 108, and below the NMOS gate oxide 108 is an NMOS channel 110. Surrounding the NMOS gate 106 is an NMOS liner 112, and surrounding the NMOS liner 112 is an NMOS spacer 114. An NMOS source/drain 116 extends from the NMOS channel 110 in a substrate 118. An NMOS cap 120, such as a nitride cap, helps to protect the NMOS gate 106 during subsequent processing steps.

The PMOS device 104 includes a PMOS gate 122. Below the PMOS gate 122 is a PMOS gate oxide 124, and below the PMOS gate oxide 124 is a PMOS channel 126. Surrounding the PMOS gate 122 is a PMOS liner 128, and surrounding the PMOS liner 128 is a PMOS spacer 130. A PMOS source/drain 132 extends from the PMOS channel 126 in the substrate 118. A PMOS cap 134, such as a nitride cap, helps to protect the PMOS gate 122 during subsequent processing steps.

Both the NMOS device 102 and the PMOS device 104 may contain a source/drain extension 136 formed by a low to medium-dose implant to facilitate dimensional reductions for the scaling of the integrated circuit system 100.

A shallow trench isolation (“STI”) 138 in the substrate 118 separates the NMOS device 102 and the PMOS device 104. For purposes of illustration, the STI 138 may be made from a dielectric material such as silicon dioxide (“SiO₂”), and the substrate 118 may be made from a semiconductor material such as silicon (Si).

The integrated circuit system 100 further includes an NMOS shallow recess 140 and a PMOS shallow recess 142 formed within the substrate 118. The NMOS shallow recess 140 and the PMOS shallow recess 142 can be formed during an over-etch of the NMOS spacer 114 and the PMOS spacer 130, respectively. By way of example, the NMOS shallow recess 140 and the PMOS shallow recess 142 can be formed to a depth of about 30 to about 60 nanometers.

Referring now to FIG. 2, therein is shown the structure of FIG. 1 after formation of an insulation layer 200. The insulation layer 200 is deposited over the integrated circuit system 100 and may include materials such as an oxide. However, it is to be understood that the present invention is not to be limited to this particular example. In accordance with the invention, the insulation layer 200 may include any material that helps to block the deposition of a subsequent layer, such as a silicon germanium layer. As an exemplary illustration, the thickness of the insulation layer 200 can range from about 20 to about 50 nanometers.

Referring now to FIG. 3, therein is shown the structure of FIG. 2 after selective etching. A first mask layer 300 is deposited over the NMOS device 102 and an etch process, such as a reactive ion etch, is employed to remove selected portions of the insulation layer 200 formed over the PMOS device 104. The first mask layer 300 and the insulation layer 200 protect the NMOS device 102 from the etch process. This etch process exposes a portion of the PMOS source/drain 132.

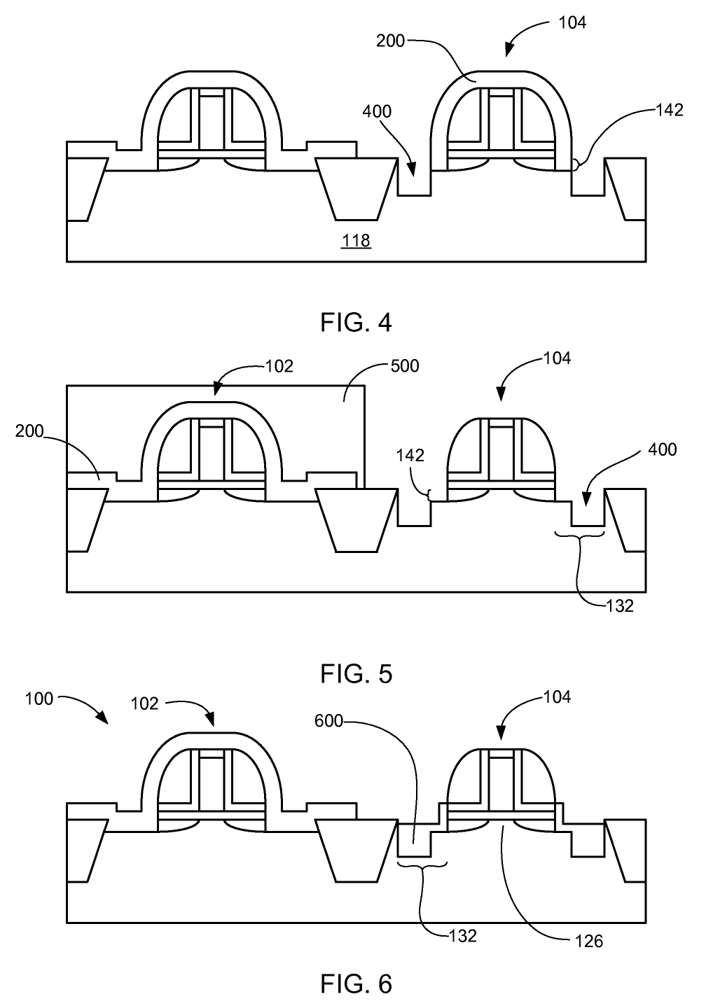

Referring now to FIG. 4, therein is shown the structure of FIG. 3 after the formation of a PMOS recess 400 within the substrate 118. During this process step the PMOS recess 400 is formed by an etch process that is highly selective to the material chosen for the substrate 118, for example. Notably, the formation of the PMOS recess 400 can be controlled by the presence or absence of the insulation layer 200 formed over the PMOS device 104.

Per this embodiment, the PMOS recess 400 is formed adjacent to and below the PMOS shallow recess 142 due to the presence of the insulation layer 200. By way of example, the PMOS recess 400 can be formed to a depth of about 60 to about 120 nanometers. Preferably, the first mask layer 300, of FIG. 3, is removed before the etch step that forms the PMOS recess 400. By removing the fist mask layer 300 before forming the PMOS recess 400, the uniformity of depth of the PMOS recess 400 can be improved.

Referring now to FIG. 5, therein is shown the structure of FIG. 4 after further processing. A second mask layer 500 is formed over the NMOS device 102 and an etch process is employed to remove remaining portions of the insulation layer 200, of FIG. 4, formed over the PMOS device 104. After removal of the insulation layer 200 from over the PMOS device 104, the PMOS shallow recess 142 is exposed. The PMOS source/drain 132, which includes the PMOS shallow recess 142 and the PMOS recess 400, is now characterized by a “step-shaped” configuration.

Additionally, the PMOS device 104 may undergo a cleaning step to remove surface contaminants, such as particles, organics and native oxides.

Referring now to FIG. 6, therein is shown the structure of FIG. 5 after the selective formation of a strain inducing layer 600 over the PMOS source/drain 132. Notably, the present inventors have discovered that the design of the strain inducing layer 600 helps to prevent the PMOS channel 126 from shorting and causing an undesirable leakage current, which can lead to failure of the integrated circuit system 100. Channel shorting commonly occurs when the drain field extends too far into the channel region and contacts the source, thereby causing punch-through of the majority carriers.

Generally, the present inventors have discovered that the proximity effect of the strain inducing layer 600 can be enhanced by tailoring the PMOS source/drain 132 configuration to suppress short channel effects. More specifically, the present inventors have discovered that short channel effects can be minimized by forming the PMOS source/drain 132 in a step-shaped configuration. For purposes of illustration only, it is believed that the step-shaped configuration of the PMOS source/drain 132 and the strain inducing layer 600, which is subsequently formed over the PMOS source/drain 132, reduces the loss of halo implant dopants and the impact of lateral diffusion of the strain inducing layer 600.

However, it is to be understood that the PMOS source/drain 132 is not to be limited to a particular configuration or depth. In accordance with the present embodiment, the PMOS source/drain 132 may include any configuration and/or depth profile that reduces short channel effects.

Notably, the strain inducing layer 600 may also introduce strain within the PMOS channel 126, thereby improving the performance of the PMOS device 104. It will be appreciated by those skilled in the art that an appropriately applied strain to the channel region of a transistor device may enhance the amount of current that can flow through the device.

By way of example, the present invention may employ the strain inducing layer 600 made from materials including silicon germanium, or more specifically, selectively grown epitaxial silicon germanium, to induce strain within the PMOS channel 126. Moreover, the strain inducing layer 600 may include an in-situ p-type doped epitaxially grown silicon germanium layer, or the strain inducing layer 600 can be doped by a p-type shallow energy implant (e.g.—about 1 to about 2 keV). However it is to be understood that the strain inducing layer 600 is not to be limited to any particular type of material or doping method. In accordance with the present embodiment, the strain inducing layer 600 may include any material or doping method that is engineered to induce strain and suppress short channel effects within the PMOS channel 126.

Furthermore, the thickness of the strain inducing layer 600 deposited may include any thickness that appropriately alters the strain and/or suppress' the short channel effects within the PMOS channel 126.

Notably, the present inventors have discovered that the p-type dopant concentration of the strain inducing layer 600 can detrimentally affect the strain within the PMOS channel 126. The present inventors have discovered that if the concentration of the p-type dopant becomes too high within the strain inducing layer 600 then the strain inducing layer 600 can become relaxed and lose its ability to impart strain within the PMOS channel 126.

Additionally, the second mask layer 500, of FIG. 5, can be removed from over the NMOS device 102 either before or after the deposition step that forms the strain inducing layer 600.

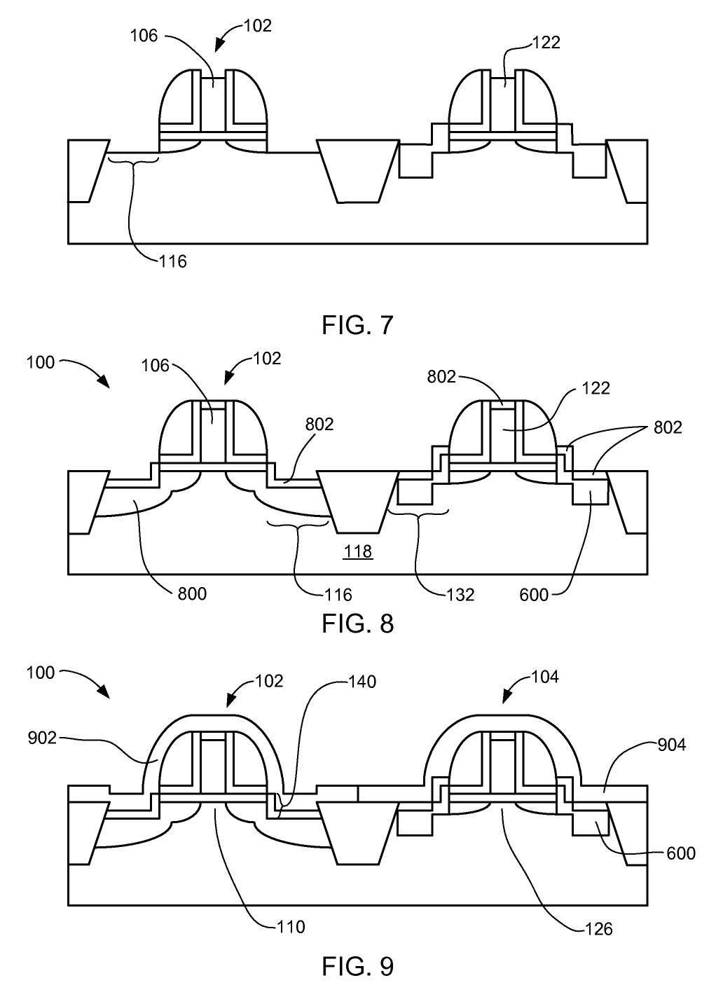

Referring now to FIG. 7, therein is shown the structure of FIG. 6 after the removal of the insulation layer 200, of FIG. 6, from over the NMOS device 102. By removing the insulation layer 200, the NMOS source/drain 116 is exposed for further processing. Additionally, the NMOS cap 120, of FIG. 1, and the PMOS cap 134, of FIG. 1, are removed from over the NMOS gate 106 and the PMOS gate 122, respectively.

Referring now to FIG. 8, therein is shown the structure of FIG. 7 after further processing. During this process step a high-dose source/drain implant forms a doped NMOS source/drain 800 within the NMOS device 102.

An anneal may also be performed after the high-dose source/drain implant to repair lattice damage, to electrically activate the dopants, and/or to minimize dopant diffusion within the substrate 118. Furthermore, to improve contact formation with the active areas of the integrated circuit system 100, a silicide or salicide process may be employed to form a low resistivity interface 802. By way of example, the low resistivity interface 802 can be formed over the NMOS source/drain 116, the NMOS gate 106, the PMOS source/drain 132, and the PMOS gate 122. It is to be understood that the low resistivity interface 802 may include any conducting compound that forms an interface between the substrate 118 and the strain inducing layer 600 that is thermally stable and provides uniform electrical properties with low resistance. For purposes of illustration, the low resistivity interface 802 may include materials such as, refractory metals.

Referring now to FIG. 9, therein is shown the structure of FIG. 8 after deposition of a first dielectric layer 902 and a second dielectric layer 904. The first dielectric layer 902 is deposited over the NMOS device 102 and may be engineered to promote a tensile strain within the NMOS channel 110. By way of example, the first dielectric layer 902 may include a silicon nitride layer deposited by a plasma enhanced chemical vapor deposition process. The tensile strain within the first dielectric layer 902 can be modulated by deposition parameters, such as, reactant flow rates, pressure, RF power, etc.

Notably, the proximity of the first dielectric layer 902 to the NMOS channel 110 is facilitated by the formation of the NMOS shallow recess 140. By way of example, the NMOS shallow recess 140 allows the placement of the first dielectric layer 902 closer to the NMOS channel 110, thereby promoting current enhancing stress within the NMOS channel 110.

The second dielectric layer 904 is deposited over the PMOS device 104 and may be engineered to promote a compressive strain within the PMOS channel 126. By way of example, the second dielectric layer 904 may include a silicon nitride layer deposited by a plasma enhanced chemical vapor deposition process. The compressive strain within the second dielectric layer 904 can be modulated by deposition parameters, such as, reactant flow rates, pressure, RF power, etc.

Notably, the second dielectric layer 904 can augment and/or enhance the compressive strain effects of the strain inducing layer 600 upon the PMOS channel 126.

It has been discovered by the present inventors, that the integrated circuit system 100 of the present invention facilitates the incorporation of both NMOS and PMOS channel stress, thereby improving the current carrying capability of the integrated circuit system 100.

### Second Embodiment

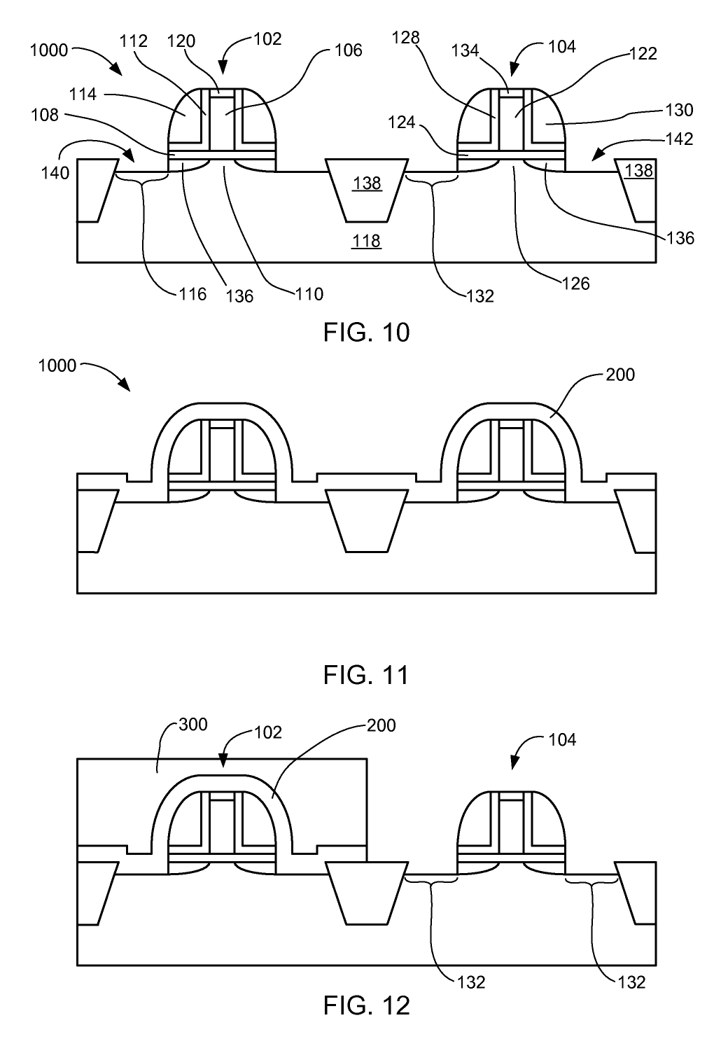

FIGS. 10-17 depict by way of example and not by limitation, an exemplary process flow for the formation of an integrated circuit system 1000, and it is not to be construed as limiting. Generally, the second embodiment teaches how to integrate an enhanced tensile strain feature, such as a recessed NMOS source/drain region, with a PMOS source/drain region that includes a strain inducing feature.

Referring now to FIG. 10, therein is shown the integrated circuit system 1000 in an initial stage of manufacture in accordance with an embodiment of the present invention. The integrated circuit system 1000 includes the NMOS device 102, the PMOS device 104, the NMOS gate 106, the NMOS gate oxide 108, the NMOS channel 110, the NMOS liner 112, the NMOS spacer 114, the NMOS source/drain 116, the substrate 118, the NMOS cap 120, the PMOS gate 122, the PMOS gate oxide 124, the PMOS channel 126, the PMOS liner 128, the PMOS spacer 130, the PMOS source/drain 132, the PMOS cap 134, the source/drain extension 136, the shallow trench isolation (“STI”) 138, the NMOS shallow recess 140, and the PMOS shallow recess 142. By way of example, the NMOS shallow recess 140 and the PMOS shallow recess 142 can be formed to a depth of about 30 to about 60 nanometers. Since the structure and elements of FIG. 10 are the same as the structure and elements of FIG. 1, identical numerals have been used and explanations thereof are omitted.

Notably, the integrated circuit system 1000 includes the NMOS shallow recess 140 formed adjacent the NMOS channel 110. The design of the NMOS shallow recess 140 adjacent the NMOS channel 110 is significant because it allows a subsequently deposited tensile strained layer to exert an increased strain effect upon the NMOS channel 110 due to its enhanced proximity. By way of example, the NMOS shallow recess 140 can be formed by over-etching the NMOS spacer 114.

Referring now to FIG. 11, therein is shown the structure of FIG. 10 after formation of the insulation layer 200. The insulation layer 200 is deposited over the integrated circuit system 1000 and may include materials such as an oxide. However, it is to be understood that the present invention is not to be limited to this particular example. In accordance with the invention, the insulation layer 200 may include any material that helps to block the deposition of a subsequent layer, such as a silicon germanium layer. As an exemplary illustration, the thickness of the insulation layer 200 can range from about 20 to about 50 nanometers.

Referring now to FIG. 12, therein is shown the structure of FIG. 11 after etching the insulation layer 200. The first mask layer 300 is deposited over the NMOS device 102 and an etch process, such as an oxide etch, can be employed to remove the insulation layer 200 formed over the PMOS device 104. The first mask layer 300 and the insulation layer 200 protect the NMOS device 102 from the etch process. This etch process exposes the PMOS source/drain 132.

Additionally, the PMOS device 104 may undergo a cleaning step to remove surface contaminants, such as particles, organics and native oxides.

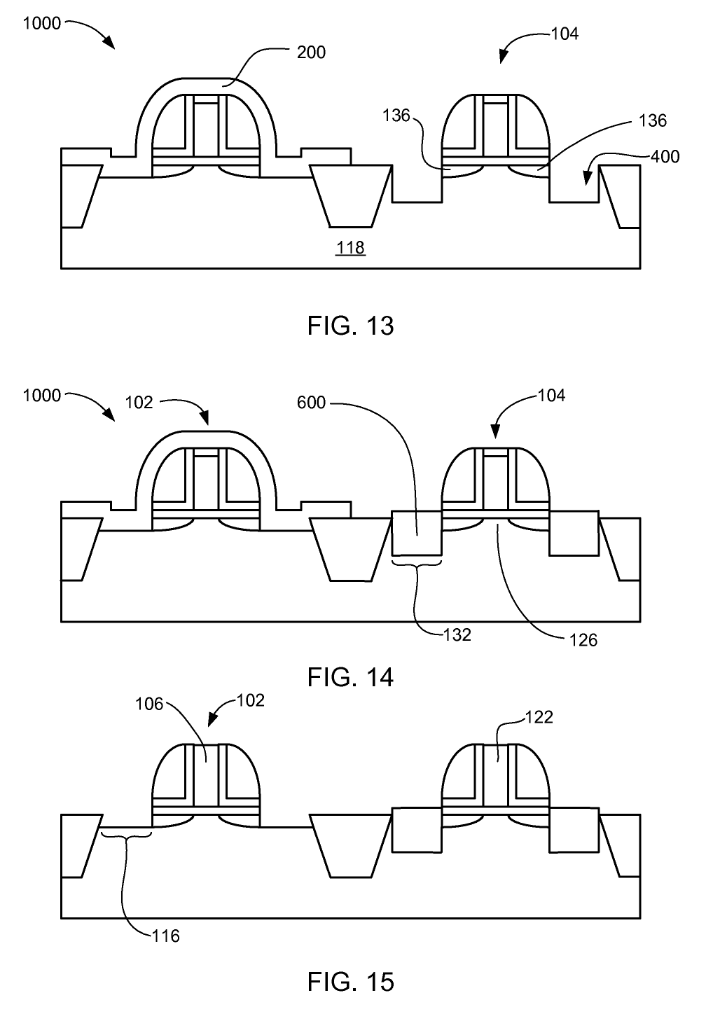

Referring now to FIG. 13, therein is shown the structure of FIG. 12 after the formation of the PMOS recess 400 within the substrate 118. During this process step the PMOS recess 400 is formed by an etch process that is highly selective to the material chosen for the substrate 118, for example. Notably, the formation of the PMOS recess 400 can be controlled by the presence or absence of the insulation layer 200 formed over the PMOS device 104. Per this embodiment, the PMOS recess 400 is formed adjacent to the source/drain extension 136 due to the absence of the insulation layer 200 formed over the PMOS device 104. By way of example, the PMOS recess 400 can be formed to a depth of about 60 to about 120 nanometers. The first mask layer 300, of FIG. 12, can be removed before the etch step that forms the PMOS recess 400. By removing the fist mask layer 300 before forming the PMOS recess 400, the uniformity of depth of the PMOS recess 400 can be improved.

Referring now to FIG. 14, therein is shown the structure of FIG. 13 after the selective formation of the strain inducing layer 600 over the PMOS source/drain 132. Notably, the strain inducing layer 600 is designed and engineered to introduce strain within the PMOS channel 126, thereby improving the performance of the PMOS device 104. It will be appreciated by those skilled in the art that an appropriately applied strain to the channel region of a transistor device may enhance the amount of current that can flow through the device.

By way of example, the present invention may employ the strain inducing layer 600 made from materials including silicon germanium, or more specifically, selectively grown epitaxial silicon germanium, to induce strain within the PMOS channel 126. Moreover, the strain inducing layer 600 may include an in-situ p-type doped epitaxially grown silicon germanium layer, or the strain inducing layer 600 can be doped by a p-type shallow energy implant (e.g.—about 1 to about 2 keV). However it is to be understood that the strain inducing layer 600 is not to be limited to any particular type of material or doping method. In accordance with the present embodiment, the strain inducing layer 600 may include any material or doping method that is engineered to induce strain within the PMOS channel 126.

Furthermore, the thickness of the strain inducing layer 600 deposited may include any thickness that appropriately alters the strain within the PMOS channel 126.

Notably, the present inventors have discovered that the p-type dopant concentration of the strain inducing layer 600 can detrimentally affect the strain within the PMOS channel 126. The present inventors have discovered that if the concentration of the p-type dopant becomes too high within the strain inducing layer 600 then the strain inducing layer 600 can become relaxed and lose its ability to impart strain within the PMOS channel 126.

Referring now to FIG. 15, therein is shown the structure of FIG. 14 after the removal of the insulation layer 200, of FIG. 14, from over the NMOS device 102. By removing the insulation layer 200, the NMOS source/drain 116 is exposed for further processing. Additionally, the NMOS cap 120, of FIG. 10, and the PMOS cap 134, of FIG. 10, are removed from over the NMOS gate 106 and the PMOS gate 122, respectively.

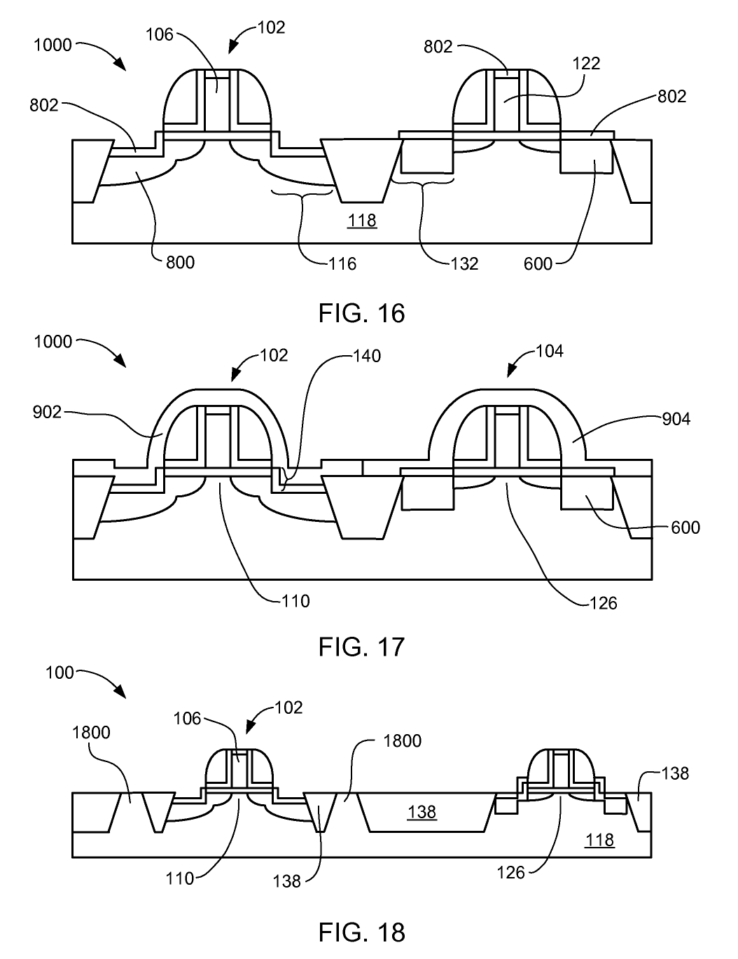

Referring now to FIG. 16, therein is shown the structure of FIG. 15 after further processing. During this process step a high-dose source/drain implant forms the doped NMOS source/drain 800 within the NMOS device 102. An anneal may also be performed after the high-dose source/drain implant to repair lattice damage, to electrically activate the dopants, and/or to minimize dopant diffusion within the substrate 118. Furthermore, to improve contact formation with the active areas of the integrated circuit system 1000, a silicide or salicide process may be employed to form the low resistivity interface 802. By way of example, the low resistivity interface 802 can be formed over the NMOS source/drain 116, the NMOS gate 106, the PMOS source/drain 132, and the PMOS gate 122. It is to be understood that the low resistivity interface 802 may include any conducting compound that forms an interface between the substrate 118 and the strain inducing layer 600 that is thermally stable and provides uniform electrical properties with low resistance. For purposes of illustration, the low resistivity interface 802 may include materials such as, refractory metals.

Referring now to FIG. 17, therein is shown the structure of FIG. 16 after deposition of the first dielectric layer 902 and the second dielectric layer 904. The first dielectric layer 902 is deposited over the NMOS device 102 and may be engineered to promote a tensile strain within the NMOS channel 110. By way of example, the first dielectric layer 902 may include a silicon nitride layer deposited by a plasma enhanced chemical vapor deposition process. The tensile strain within the first dielectric layer 902 can be modulated by deposition parameters, such as, reactant flow rates, pressure, RF power, etc.

Notably, the proximity of the first dielectric layer 902 to the NMOS channel 110 is facilitated by the formation of the NMOS shallow recess 140. By way of example, the NMOS shallow recess 140 allows the placement of the first dielectric layer 902 closer to the NMOS channel 110, thereby promoting current enhancing stress within the NMOS channel 110.

The second dielectric layer 904 is deposited over the PMOS device 104 and may be engineered to promote a compressive strain within the PMOS channel 126. By way of example, the second dielectric layer 904 may include a silicon nitride layer deposited by a plasma enhanced chemical vapor deposition process. The compressive strain within the second dielectric layer 904 can be modulated by deposition parameters, such as, reactant flow rates, pressure, RF power, etc. Notably, the second dielectric layer 904 can augment and/or enhance the compressive strain effects of the strain inducing layer 600 upon the PMOS channel 126.

It has been discovered by the present inventors, that the integrated circuit system 1000 of the present invention facilitates the incorporation of both NMOS and PMOS channel stress, thereby improving the current carrying capability of the integrated circuit system 1000.

### Third Embodiment

Referring now to FIG. 18, therein is shown the structure of FIG. 9 with a strain suppressing feature 1800 in accordance with the first embodiment of the present invention. However, it is to be understood that the strain suppressing feature 1800 may also be employed with FIG. 17 of the second embodiment of the present invention, as well.

In this embodiment, the STI 138 is made of silicon dioxide (“SiO₂”) and the substrate 118 is made of Si. Thus, the difference in thermal expansion between the SiO₂ and the Si produces strain in the PMOS channel 126 and in the NMOS channel 110. Strain in the PMOS channel 126 improves performance by increasing hole mobility. However, strain in the NMOS channel 110 degrades performance by reducing electron mobility.

It has been unexpectedly discovered that incorporating the strain suppressing feature 1800, which is generally rectangular, parallel to the length of the NMOS gate 106 and in the STI 138 reduces strain to the NMOS channel 110. Thus, the strain suppressing feature 1800 is perpendicular to the direction of the strain. The strain suppressing feature 1800 acts similarly as a bulwark in the sea that is used to suppress the tide from the sea. Likewise, the strain suppressing feature 1800, in the vicinity thereof, suppresses the strain generated by the STI 138.

In one embodiment, the strain suppressing feature 1800 is formed during photolithographic processes used to form the STI 138. A mask is used to shield the regions where the strain suppressing feature 1800 will be formed. The STI 138 is then formed around the strain suppressing feature 1800. Thus in this embodiment, the strain suppressing feature 1800 is a region of the substrate 118 that has not been formed into the STI 138, but instead remains unaltered by the STI-forming process.

The distance between the strain suppressing feature 1800 and the NMOS device 102 affects the strain on the NMOS device 102. Strain increases as the distance increases. Thus, strain is controlled, adjusted to a predetermined level, and optimized by adjusting the position of the strain suppressing feature 1800 and adjusting the distance between the strain suppressing feature 1800 and the NMOS device 102.

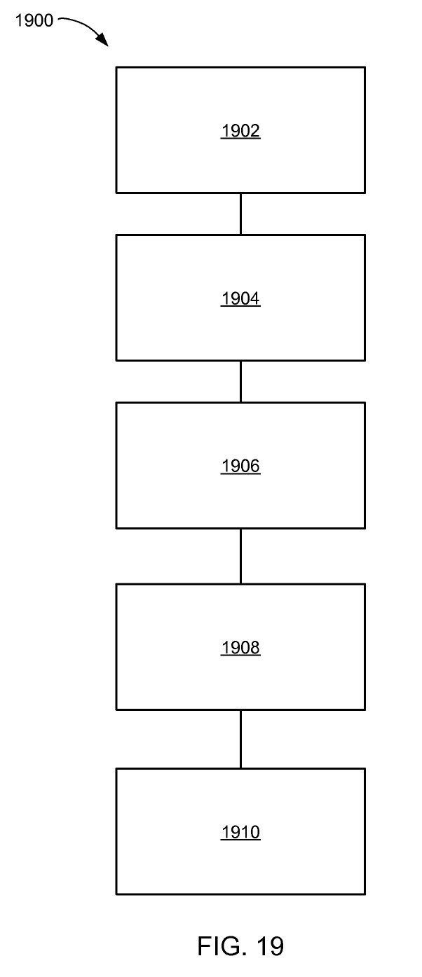

Referring now to FIG. 19, therein is shown a flow chart of an integrated circuit system 1900 for the integrated circuit system 100 and 1000 in accordance with an embodiment of the present invention. The integrated circuit system 1900 includes providing a substrate with a PMOS device and an NMOS device in a block 1902; forming an NMOS shallow recess within the substrate in a block 1904; forming a PMOS recess within the substrate in a block 1906; forming a strain inducing layer over the PMOS recess in a block 1908; and forming a first dielectric layer over the NMOS device and a second dielectric layer over the PMOS device in a block 1910.

It has been discovered that the present invention thus has numerous aspects. A principle aspect is that the present invention helps to suppress short channel effects associated with dimensional scaling of a PMOS device by configuring the PMOS source/drain to suppress punch-through occurrences.

Another aspect of the present invention is that it provides increased strain within the channel region of a PMOS device by depositing a strain inducing layer adjacent the PMOS channel region.

Another aspect of the present invention is that it provides increased strain within the channel region of an NMOS device by depositing a dielectric layer in close proximity to the NMOS channel region due to the formation of an NMOS shallow recess.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system of the present invention furnishes important and heretofore unknown and unavailable solutions, capabilities, and functional aspects for enhancing NMOS and PMOS device performance. The resulting processes and configurations are straightforward, cost-effective, uncomplicated, highly versatile and effective, can be implemented by adapting known technologies, and are thus readily suited for efficiently and economically manufacturing integrated circuit package devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations, which fall within the scope of the included claims. All matters hithertofore set forth herein or shown in the accompanying drawings are to be interpreted in an illustrative and non-limiting sense.

What is claimed is:

1. An integrated circuit system comprising:
providing a substrate with a PMOS device and an NMOS device;
forming an NMOS shallow recess within the substrate;
forming a PMOS recess within the substrate;
forming a strain inducing layer over the PMOS recess; and
forming a first dielectric layer over the NMOS device and a second dielectric layer over the PMOS device.

2. The system as claimed in claim 1 wherein:
forming the PMOS recess includes forming the PMOS recess adjacent a PMOS shallow recess.

3. The system as claimed in claim 1 wherein:
forming the strain inducing layer prevents short channel effects.

4. The system as claimed in claim 1 wherein:
forming the strain inducing layer induces strain within the PMOS device.

5. The system as claimed in claim 1 wherein:
forming the NMOS shallow recess allows the first dielectric layer to induce strain within the NMOS device.

6. An integrated circuit system comprising:
providing a substrate with a PMOS device and an NMOS device;
forming a PMOS shallow recess and an NMOS shallow recess;
forming a PMOS recess adjacent the PMOS shallow recess;
forming a strain inducing layer over the PMOS recess and the PMOS shallow recess; and
forming a first dielectric layer over the NMOS device and a second dielectric layer over the PMOS device.

7. The system as claimed in claim 6 further comprising:
forming the PMOS shallow recess and the NMOS shallow recess to a depth of about 30 nanometers to about 60 nanometers.

8. The system as claimed in claim 6 further comprising:
forming the PMOS shallow recess and the PMOS recess to include a step-shaped configuration.

9. The system as claimed in claim 6 further comprising:
forming a low resistivity interface over an NMOS source/drain, an NMOS gate, a PMOS source/drain, and a PMOS gate.

10. The system as claimed in claim 6 further comprising:
forming a strain suppressing feature.

11. An integrated circuit system comprising:
a substrate with a PMOS device and an NMOS device;
an NMOS shallow recess within the substrate;
a PMOS recess within the substrate;
a strain inducing layer over the PMOS recess; and
a first dielectric layer over the NMOS device and a second dielectric layer over the PMOS device.

12. The system as claimed in claim 11 wherein:
the PMOS recess is adjacent a PMOS shallow recess.

13. The system as claimed in claim 12 wherein:
the PMOS shallow recess and the NMOS shallow recess are about 30 nanometers to about 60 nanometers deep.

14. The system as claimed in claim 12 wherein:
the PMOS shallow recess and the PMOS recess include a step-shaped configuration.

15. The system as claimed in claim 11 wherein:
the strain inducing layer prevents short channel effects.

16. The system as claimed in claim 11 wherein:
the strain inducing layer induces strain within the PMOS device.

17. The system as claimed in claim 11 wherein:
the strain inducing layer includes silicon and germanium.

18. The system as claimed in claim 11 wherein:
the NMOS shallow recess allows the first dielectric layer to induce strain within the NMOS device.

19. The system as claimed in claim 11 further comprising:
a low resistivity interface over an NMOS source/drain, an NMOS gate, a PMOS source/drain, and a PMOS gate.

20. The system as claimed in claim 11 further comprising:
a strain suppressing feature.
